(19) United States
(12) Patent Application Publication
(10) Pub. No.: US 2026/0190300 A1
(43) Pub. Date: Jul. 2, 2026

(54) Modular cooling system and method for adaptive configuration of components according to a cooling demand of a physical space

(71) Applicant: Heatcraft Refrigeration Products LLC, Stone Mountain, GA (US)

(72) Inventors: Michael Pennington, Loganville, GA (US); Sajjad Khan, Conyers, GA (US); Karthick Kuppusamy, Tamil Nadu (IN); Daqing Li, Snellville, GA (US); Douglas Cole, Columbus, GA (US); Eric Moen, Rising Fawn, GA (US)

(21) Appl. No.: 19/006,715

(22) Filed: Dec. 31, 2024

(51) Int. Cl. H05K 7/20

(52) U.S. Cl. CPC H05K 7/20836; H05K 7/20354; H05K 7/20827

(57) ABSTRACT

A method for operating a cooling system for a data center comprises receiving temperature of a coolant from a temperature sensor circuit and determine whether the temperature is more than a threshold temperature. The method further comprises determining one or more racks that meet a cooling capacity associated with the cooling demand of the data center and determining one or more pumps that meet a required flow of the refrigerant according to the cooling demand of the data center if it is determined that the temperature is more than the threshold temperature. The method further comprises communicating a first electronic signal to each of the one or more racks to activate the one or more racks and communicating a second electronic signal to each of the one or more pumps to activate the one or more pumps.

### TECHNICAL FIELD

This disclosure relates generally to cooling systems. More particularly, this disclosure relates to a modular cooling system and method for adaptive configuration of components according to a cooling demand of a physical space.

### BACKGROUND

Cooling systems are used to cool spaces, such as data centers, residential dwellings, commercial buildings, and/or refrigeration units. These systems cycle a refrigerant (also referred to as charge) that is used to cool the spaces.

### SUMMARY OF THE DISCLOSURE

Some of the conventional data center cooling solutions use liquid-based chiller systems to dissipate heat generated by servers and other computing devices within the data centers. The cooling needs of a data center may fluctuate depending on the processing load performed by the data center. Further, the available power or energy resources for running the data center may vary depending on various factors, such as power grid blackouts or changes (e.g., increase or decrease) in processing load to be handled by the data center. The power or energy resources available to the site where data center is located may also be used to run the cooling system of the data center. In some cases, if the available power resource for the data center is exhausted, one or more additional backup generators may be implemented to provide supplementary power to the data center. Further, the cooling demand of the data center may fluctuate depending on the processing load of the data center. For example, during peak operational hours, the cooling demand of the data center may increase proportionally to the increase in the processing load; and during off-peak hours, the cooling demand of the data center may decrease proportionally to the decrease in the processing load. The conventional data center cooling solutions are not equipped to adapt to the fluctuations in the processing load of the data center, fluctuations in the available power resources for the data center, and/or fluctuations in the cooling demand of the data center.

Further, in some conventional data center cooling systems where liquid-based chillers are used, the compressors and condensers are integrated into a single unit, and therefore, they cannot be independently controlled. This poses a limit in the controlling of the cooling system, for example, to isolate a failed compressor or a failed condenser from the other components in the chiller. In an event of a failed component in a chiller, the entire chiller may need to be taken offline.

Further, the conventional data center cooling solutions lack scalability. For example, if any expansion or modification is needed to be made to the cooling infrastructure, it affects the entire infrastructure. In other words, adding or removing components requires major changes to the existing cooling infrastructure. This makes such conventional data center cooling system rigid and difficult to scale.

Further, the conventional data center cooling solutions lack modular components. For example, in a conventional data center cooling system, each component is directly connected to a next component per the cooling infrastructure to provide cooling to the data center. Thus, if a component fails or goes offline, the entire cooling process may be interrupted.

The disclosed system is configured to provide a technical solution to these and other technical problems of the conventional data center cooling systems. Certain technical advantages and technological improvements to the conventional cooling systems are described below in conjunction with certain embodiment of the disclosed cooling system.

In some embodiments, the disclosed system implements a modular cooling architecture that separates key components of the cooling systems by multi-valve manifolds. In other words, in the disclosed system, each two adjacent key components are separated by a multi-valve manifold. This allows the disclosed system to selectively activate a specific combination of components based on the current cooling demands of the data center, operational status of each component, and available power to the site where the cooling system and its cooling system are located. Unlike traditional data center cooling systems where components are directly connected in a preset, fixed configuration, the disclosed modular cooling system allows each component to be controlled, maintained, and replaced individually without affecting the entire cooling infrastructure.

In some embodiments, in the disclosed modular cooling system, the refrigerant flows through a network of independent, modular components to provide cooling to the data center. For example, in response to receiving a cooling demand to provide cooling to the data center, the disclosed system determines which combination of components (e.g., rack(s), compressor(s), pump(s), gas cooler(s), condenser(s), and evaporator(s)) to activate to facilitate the current cooling demand. In response, the refrigerant flows through the activated components. For example, the refrigerant may flow through the activated compressor(s) housed in array(s) of activated rack(s), where the pressure and temperature of the refrigerant are increased. The high pressure, high temperature refrigerant is routed through multi-valve manifolds that direct its flow to activated condenser(s) or gas cooler(s), where heat from the refrigerant is dissipated into the outdoor environment. The refrigerant then flows through multi-valve manifolds which direct the refrigerant to the activated evaporator(s), where it transfers its cooling to a secondary coolant (e.g., water) used by the internal cooling system of the data center. The cooled coolant flows through multi-valve manifolds which direct the refrigerant to the activated pump(s) to pump the coolant into the internal cooling system of the data center, where it absorbs heat from the computing devices within the data center. The coolant may be liquid, vapor, or two-phase (mixture of liquid and vapor). When circulated through the data center, the warmed coolant returns to the cooling infrastructure, and the process repeats until the cooling demand is met. In some embodiments, the pumps may pump the coolant into the data center. In some embodiments, the pumps may pump the coolant out of the data center.

In some embodiments, the disclosed cooling system is configured with redundant components to allow switching between counterpart components. For example, the disclosed cooling system may be configured to provide more than 100% of the cooling demand (such as 150%, 200%, or 300%, of the cooling demand) of the data center, which each component handling a portion of the total load (such as 5%, 10%, or 15% of the total load). The disclosed cooling system may cycle through different combinations of components to meet the 100% of the cooling demand, while the redundant components are offline.

In some embodiments, the disclosed cooling system can change the combination the active components by closing and opening specific valves in the multi-valve manifolds to direct the refrigerant flow to the selected components and prevent the refrigerant flow to the rest of the components. This allows the disclosed cooling system to dynamically change the route of the refrigerant flow through the configured combination of components that is determined according to the cooling demand, operational status of components, and available power or energy resources.

In some embodiments, the disclosed system is configured to adapt to the fluctuations in the processing load of the data center, fluctuations in the available power resources for the data center, and fluctuations in the cooling demand of the data center. For example, if the processing load in the data center increases, this may result in an increase in the outlet temperature of the coolant at the outlet of the data center. The disclosed cooling system may detect the increased outlet temperature of the coolant. In response, the disclosed cooling system may activate additional rack(s) and/or compressor(s) to meet the increased cooling demand. Otherwise, if the processing load in the data center decrease to be less than a baseline level, the disclosed cooling system may deactivate one or more of the active racks and/or compressors to not provide an excess cooling to the data center.

In another example, if the inlet temperature of the coolant at the inlet of the data center increases, the disclosed cooling system detect that the cooling capacity does not meet the cooling demand of the data center. In response, the disclosed cooling system may activate additional pump(s) to increase the flow rate of the refrigerant and/or increase the speed of the currently active pump(s). Otherwise, if the inlet temperature of the coolant at the inlet of the data center decreases to be less than a baseline level, the disclosed system may deactivate one or more of the active pumps and/or reduce the speed of the active pumps to not provide excess refrigerant flow rate.

In some embodiments, the disclosed cooling system is configured to provide load balancing across the plurality of components. To this end, the disclosed cooling system monitors the operational status of each component, including the load carried by each component. In response, the disclosed cooling system determines a scheduling protocol for activation and deactivation of components to balance their runtime and distribute the load substantially evenly among the components.

In some embodiments, the disclosed cooling system is configured to detect and mitigate failed components. The disclosed cooling system includes sensor circuits that monitor and capture component attributes, such as temperature, pressure, and voltage level for each component within the plurality of components of the cooling system. The disclosed cooling system receives sensor data (that included the captured attributes) from the sensor circuits and compare the received sensor data to an expected data. If a component's attribute deviates from an expected level by more a predefined threshold, the disclosed cooling system may determine that the component has failed. In response, the disclosed system may isolate the failed component by communicating an electronic signal to multi-valve manifolds connected to the failed component to close the valve which allows refrigerant flow into the failed component and close the valve which allows the refrigerant flow out of the failed component. The disclosed cooling system may identify and activate one or more counterpart components to take over the operational load of the failed component. This leads to reducing interruption of the cooling process to the data center and a consistent and stable cooling capacity provided by the disclosed cooling system even in the event of a failed component.

In this manner, the disclosed cooling system provides the practical applications to improve the conventional data center cooling systems.

### Adaptive Configuration of Components According to a Cooling Demand of a Physical Space

In some embodiments, the cooling system comprises a cooling architecture. The cooling architecture comprises a plurality of components comprising at least one outdoor heat exchanger; at least one evaporator; at least one pump; a plurality of racks; or a plurality of multi-valve manifolds, wherein each multi-valve manifold is configured to allow a flow of refrigerant from one component to another component of said plurality of components. Each rack is configured to house at least one of a compressor, a flash tank, an accumulator, or an oil separator. The cooling system further comprises a temperature sensor circuit, positioned adjacent to a refrigerant conduit subsystem connected to a data center, and configured to capture a temperature of a coolant flowing through the refrigerant conduit subsystem.

The cooling system further comprises a controller, coupled to the cooling architecture and the temperature sensor circuit, and comprising a processor configured to receive the temperature of the coolant from the temperature sensor circuit. The processor is further configured to determine whether the received temperature is more than a threshold temperature, where the threshold temperature is associated with a cooling demand of the data center. The processor is further configured to determine one or more racks that meet a cooling capacity associated with the cooling demand of the data center, determine one or more pumps that meet a required flow of the refrigerant, according to the cooling demand of the data center, communicate a first electronic signal to each of the one or more racks, wherein the first electronic signal activates a receiving rack, and communicate a second electronic signal to each of the one or more pumps, wherein the second electronic signal activates a receiving pump, in response to determining that the received temperature is more than the threshold temperature.

### Detecting and Mitigating a Component Failure

In some embodiments, the cooling system comprises a cooling architecture. The cooling architecture comprises a plurality of components comprising at least one outdoor heat exchanger; at least one evaporator; at least one pump; a plurality of racks; or a plurality of multi-valve manifolds, wherein each multi-valve manifold is configured to allow a flow of refrigerant from one component to another component of said plurality of components. Each rack is configured to house at least one of a compressor, a flash tank, an accumulator, or an oil separator. The cooling system further comprises at least one of: a temperature sensor circuit, positioned downstream of a first component from among said plurality of components, and configured to capture a temperature of the refrigerant flowing through the first component; a pressure sensor circuit, positioned downstream of the first component, and configured to capture a pressure of the refrigerant flowing through the first component; or a voltage sensor circuit associated with the first component, and configured to capture a voltage level of the first component.

The cooling system further comprises a controller, coupled to the cooling architecture, and comprising a processor configured to receive sensor data that indicates an attribute associated with the first component, where the attribute is the temperature of the refrigerant, the pressure of the refrigerant, or the voltage level. The processor is further configured to compare the received attribute with an expected level for the attribute. The processor is further configured to determine that the first component has failed based at least in part upon the comparison, wherein determining that the first component has failed comprises determining that the received attribute deviates from the expected level for the attribute by more than a pre-defined threshold. The processor is further configured to communicate a first electronic signal to a multi-valve manifold that is connected to the first component to isolate the first component from a rest of the plurality of components in response to determining that the first component has failed, wherein the first electronic signal causes a valve that allows the refrigerant flowing into the first component to be closed.

Certain embodiments of the present disclosure may include some, or none of these advantages. These advantages and other features will be more clearly understood from the following detailed description taken in conjunction with the accompanying drawings and claims.

### BRIEF DESCRIPTION OF THE DRAWINGS

For a more complete understanding of the present disclosure, reference is now made to the following description, taken in conjunction with the accompanying drawings, in which:

FIG. 1A illustrates an example cooling system according to an embodiment of the present disclosure;

FIG. 1B illustrates an embodiment of a controller of the system of FIG. 1A;

FIG. 2 illustrates an example embodiment of one or more racks of the system of FIG. 1A;

FIG. 3 illustrates a flowchart of an example method of operating the system of FIG. 1A for adaptive configuration of components according to a cooling demand of a physical space; and

FIG. 4 illustrates a flowchart of an example method 400 of operating the system 100 of FIG. 1A for detecting and mitigating a component failure.

### DETAILED DESCRIPTION

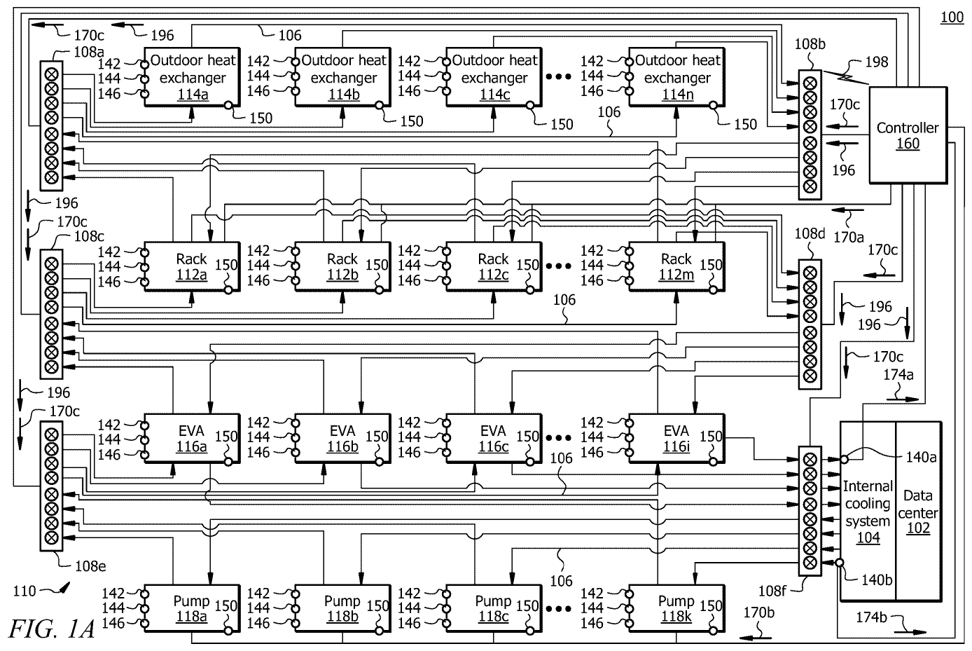

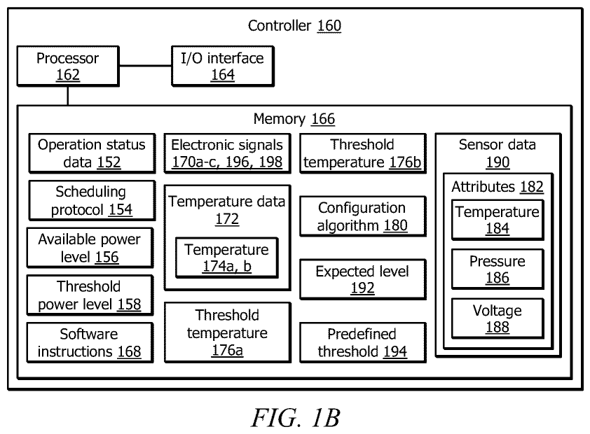

Embodiments of the present disclosure and its advantages are best understood by referring to FIGS. 1A through 4 of the drawings, like numerals being used for like and corresponding parts of the various drawings.

Some of the conventional data center cooling solutions use liquid-based chiller systems to dissipate heat generated by servers and other computing devices within the data centers. The cooling needs of a data center may fluctuate depending on the processing load performed by the data center. Further, the available power or energy resources for running the data center may vary depending on various factors, such as power grid blackouts or changes (e.g., increase or decrease) in processing load to be handled by the data center. The power or energy resources available to the site where data center is located may also be used to run the cooling system of the data center. In some cases, if the available power resource for the data center is exhausted, one or more additional backup generators may be implemented to provide supplementary power to the data center. Further, the cooling demand of the data center may fluctuate depending on the processing load of the data center. For example, during peak operational hours, the cooling demand of the data center may increase proportionally to the increase in the processing load; and during off-peak hours, the cooling demand of the data center may decrease proportionally to the decrease in the processing load. The conventional data center cooling solutions are not equipped to adapt to the fluctuations in the processing load of the data center, fluctuations in the available power resources for the data center, and/or fluctuations in the cooling demand of the data center.

Further, in some conventional data center cooling systems where liquid-based chillers are used, the compressors and condensers are integrated into a single unit, and therefore, they cannot be independently controlled. This poses a limit in the controlling of the cooling system, for example, to isolate a failed compressor or a failed condenser from the other components in the chiller. In an event of a failed component in a chiller, the entire chiller may need to be taken offline.

Further, the conventional data center cooling solutions lack scalability. For example, if any expansion or modification is needed to be made to the cooling infrastructure, it affects the entire infrastructure. In other words, adding or removing components requires major changes to the existing cooling infrastructure. This makes such conventional data center cooling system rigid and difficult to scale.

Further, the conventional data center cooling solutions lack modular components. For example, in a conventional data center cooling system, each component is directly connected to a next component per the cooling infrastructure to provide cooling to the data center. Thus, if a component fails or goes offline, the entire cooling process may be interrupted.

The disclosed system is configured to provide a technical solution to these and other technical problems of the conventional data center cooling systems. Certain technical advantages and technological improvements to the conventional cooling systems are described below in conjunction with certain embodiment of the disclosed cooling system.

In some embodiments, the disclosed system implements a modular cooling architecture that separates key components of the cooling systems by multi-valve manifolds. In other words, in the disclosed system, each two adjacent key components are separated by a multi-valve manifold. This allows the disclosed system to selectively activate a specific combination of components based on the current cooling demands of the data center, operational status of each component, and available power to the site where the cooling system and its cooling system are located. Unlike traditional data center cooling systems where components are directly connected in a preset, fixed configuration, the disclosed modular cooling system allows each component to be controlled, maintained, and replaced individually without affecting the entire cooling infrastructure.

In some embodiments, in the disclosed modular cooling system, the refrigerant flows through a network of independent, modular components to provide cooling to the data center. For example, in response to receiving a cooling demand to provide cooling to the data center, the disclosed system determines which combination of components (e.g., rack(s), compressor(s), pump(s), gas cooler(s), condenser(s), and evaporator(s)) to activate to facilitate the current cooling demand. In response, the refrigerant flows through the activated components. For example, the refrigerant may flow through the activated compressor(s) housed in array(s) of activated rack(s), where the pressure and temperature of the refrigerant are increased. The high pressure, high temperature refrigerant is routed through multi-valve manifolds that direct its flow to activated condenser(s) or gas cooler(s), where heat from the refrigerant is dissipated into the outdoor environment. The refrigerant then flows through multi-valve manifolds which direct the refrigerant to the activated evaporator(s), where it transfers its cooling to a secondary coolant (e.g., water) used by the internal cooling system of the data center. The cooled coolant flows through multi-valve manifolds which direct the refrigerant to the activated pump(s) to pump the coolant into the internal cooling system of the data center, where it absorbs heat from the computing devices within the data center. When circulated through the data center, the warmed coolant returns to the cooling infrastructure, and the process repeats until the cooling demand is met. In some embodiments, the pumps may pump the coolant into the data center. In some embodiments, the pumps may pump the coolant out of the data center.

In some embodiments, the disclosed cooling system is configured with redundant components to allow switching between counterpart components. For example, the disclosed cooling system may be configured to provide more than 100% of the cooling demand (such as 150%, 200%, or 300%, of the cooling demand) of the data center, which each component handling a portion of the total load (such as 5%, 10%, or 15% of the total load). The disclosed cooling system may cycle through different combinations of components to meet the 100% of the cooling demand, while the redundant components are offline.

In some embodiments, the disclosed cooling system can change the combination the active components by closing and opening specific valves in the multi-valve manifolds to direct the refrigerant flow to the selected components and prevent the refrigerant flow to the rest of the components. This allows the disclosed cooling system to dynamically change the route of the refrigerant flow through the configured combination of components that is determined according to the cooling demand, operational status of components, and available power or energy resources.

In some embodiments, the disclosed system is configured to adapt to the fluctuations in the processing load of the data center, fluctuations in the available power resources for the data center, and fluctuations in the cooling demand of the data center. For example, if the processing load in the data center increases, this may result in an increase in the outlet temperature of the coolant at the outlet of the data center. The disclosed cooling system may detect the increased outlet temperature of the coolant. In response, the disclosed cooling system may activate additional rack(s) and/or compressor(s) to meet the increased cooling demand. Otherwise, if the processing load in the data center decrease to be less than a baseline level, the disclosed cooling system may deactivate one or more of the active racks and/or compressors to not provide an excess cooling to the data center.

In another example, if the inlet temperature of the coolant at the inlet of the data center increases, the disclosed cooling system detect that the cooling capacity does not meet the cooling demand of the data center. In response, the disclosed cooling system may activate additional pump(s) to increase the flow rate of the refrigerant and/or increase the speed of the currently active pump(s). Otherwise, if the inlet temperature of the coolant at the inlet of the data center decreases to be less than a baseline level, the disclosed system may deactivate one or more of the active pumps and/or reduce the speed of the active pumps to not provide excess refrigerant flow rate.

In some embodiments, the disclosed cooling system is configured to provide load balancing across the plurality of components. To this end, the disclosed cooling system monitors the operational status of each component, including the load carried by each component. In response, the disclosed cooling system determines a scheduling protocol for activation and deactivation of components to balance their runtime and distribute the load substantially evenly among the components.

In some embodiments, the disclosed cooling system is configured to detect and mitigate failed components. The disclosed cooling system includes sensor circuits that monitor and capture component attributes, such as temperature, pressure, and voltage level for each component within the plurality of components of the cooling system. The disclosed cooling system receives sensor data (that included the captured attributes) from the sensor circuits and compare the received sensor data to an expected data. If a component's attribute deviates from an expected level by more a predefined threshold, the disclosed cooling system may determine that the component has failed. In response, the disclosed system may isolate the failed component by communicating an electronic signal to multi-valve manifolds connected to the failed component to close the valve which allows refrigerant flow into the failed component and close the valve which allows the refrigerant flow out of the failed component. The disclosed cooling system may identify and activate one or more counterpart components to take over the operational load of the failed component. This leads to reducing interruption of the cooling process to the data center and a consistent and stable cooling capacity provided by the disclosed cooling system even in the event of a failed component.

In this manner, the disclosed cooling system provided the practical applications to improve the conventional data center cooling systems.

### Example Cooling System

FIG. 1A illustrates an example cooling system 100 according to an embodiment of the present disclosure. In general, the cooling system 100 is configured to provide modular, flexible cooling to a data center 102 by selectively activating components based on the current cooling demand of the data center 102, dynamically routing refrigerant through multi-valve manifolds, and autonomously detecting and mitigating component failures to reduce interruptions in the cooling process for the data center 102. In some embodiments, the cooling system 100 comprises a cooling architecture 110 communicatively coupled with a controller 160 via wired and/or wireless connections. The cooling architecture 110 is controlled by the controller 160. The operations of the controller 160 are described further below in conjunction of the operational flow of the cooling system 100.

In some embodiments, the cooling architecture 110 comprises a set of arrays of modular components, including racks 112a-m (e.g., racks 112a, 112b, 112c, through 112m), outdoor heat exchangers 114a-n (e.g., outdoor heat exchangers 114a, 114b, 114c, through 114n), evaporators 116a-i (e.g., evaporators 116a, 116b, 116c, through 116i), and pumps 118a-k (e.g., pumps 118a, 118b, 118c, through 118k), where each pair of adjacent components is interconnected to each other via a multi-valve manifold 108a-f (e.g., multi-valve manifolds 108a, 108b, 108c, 108d, 108e, and 108f) as shown in the example of FIG. 1A. The illustrated embodiment of the cooling system 100 in FIG. 1A is configured to provide air conditioning to one or more physical spaces, stores, or any other type of spaces that require cooling, collectively referred to herein as a data center 102. In some embodiments, the cooling system 100 may include one or more of each of the illustrated components operably coupled to one another. In some embodiments, the cooling system 100 may include some of the illustrated components and/or additional components.

### System Components

The data center 102 may be one or more physical spaces where computing devices such as servers, workstations, virtual machines, processors, and other electronic equipment are located. The computing devices may generate heat during their operations. The data center 102 may include or be associated with an internal cooling system 104 which circulates a coolant through pipes within the data center 102 to provide cooling to the computing devices within the data center 102. The coolant of the internal cooling system 104 is cooled by the refrigerant of the cooling architecture 110 when it flows through the evaporators 116a-i where the heat is transferred from the coolant to the refrigerant. The cooled coolant is circulated through the internal cooling system 104 and cools the computing devices of the data center 102. This circulation raises the temperature of the coolant. The warmed coolant returns to the evaporators 116a-i to get cooled again. This cycle continues until the cooling demand of the data center is met.

The internal cooling system 104 may be any suitable cooling system, such as a liquid-based cooling system, an air-cooled system, or a hybrid system that provides both liquid and air cooling. The cooling architecture 110 is agnostic to the internal cooling system 104 of the data center 102, meaning that the cooling architecture 110 can interface with and support various types of internal cooling systems 104 without requiring modifications to its own design or operation. The cooling architecture 110 is also agnostic to the coolant used by the internal cooling system 104. For example, the coolant used by the internal cooling system 104 may be liquid, air, glycol-water mixture, among others.

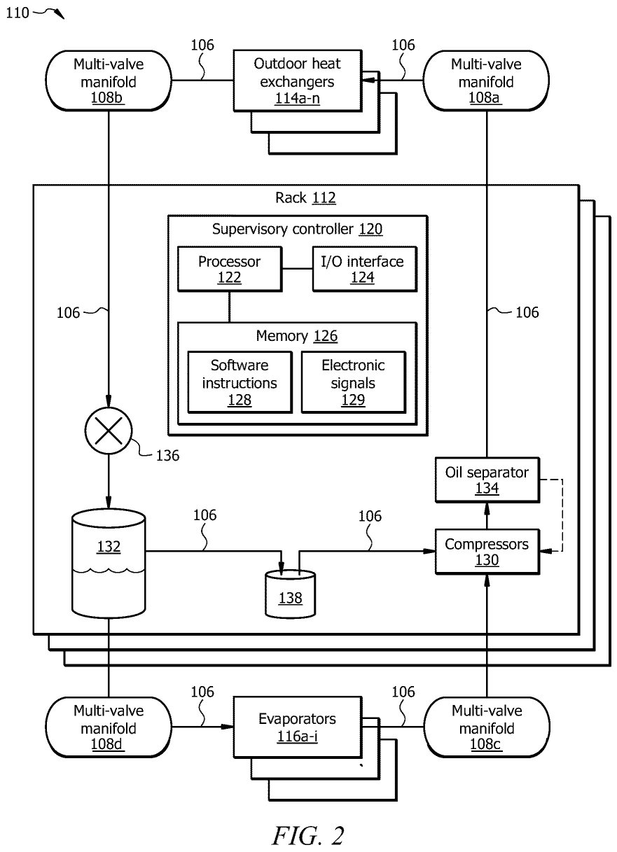

The refrigerant conduit subsystems 106 facilitate the movement of a refrigerant (also referred to herein as a working fluid) through a cooling cycle such that the refrigerant flows through the cooling architecture 110 as illustrated by arrows in FIGS. 1A and 2. The refrigerant conduit subsystem 106 includes any conduit, tubing and the like that is illustrated in FIGS. 1A and 2 fluidly connecting components of the cooling architecture 110.

### Example Multi-Valve Manifolds

Each of the multi-valve manifolds 108a-f may include two or more valves configured to control the direction and allow the flow of refrigerant between different components in the cooling architecture 110, e.g., from one component to another component. In some examples, a multi-valve manifold 108a-f may include expansion valves, flow control valves, flash gas valves, solenoid valves, motorized valves, check valves, electronic expansion valves (EEVs), and thermal expansion valves (TXVs), among others. The multi-valve manifold 108a-f may control the flow of the refrigerant automatically, through internally calibrated mechanical components, in response to pressure changes, and/or in response to instructions indicated by electronic signals received from the controller 160. Each valve in a given multi-valve manifold 108a-f may open and close (e.g., by varying degrees) to control the flow rate of the refrigerant. Each valve in each multi-valve manifold 108a-f may connect one component to another component, one component to multiple components, or multiple components to one component. Each multi-valve manifold 108a-f is fluidly coupled to the refrigerant conduit subsystem 106 that connects each adjacent pair of interconnected components of the cooling architecture 110.

As shown in FIG. 1A, the multi-valve manifold 108a allows the flow of the refrigerant from the racks 112a-m to the outdoor heat exchangers 114a-n. The multi-valve manifold 108b allows the flow of the refrigerant from the outdoor heat exchangers 114a-n back into the racks 112a-m. After the refrigerant has dissipated its heat through the outdoor heat exchangers, it may flow through the manifold 108b, which directs the refrigerant back into the racks for the next cooling cycle. The multi-valve manifold 108c allows the flow of the refrigerant from the evaporators 116a-i to the racks 112a-m. The multi-valve manifold 108c directs the refrigerant that has absorbed heat from the coolant back into the racks. The multi-valve manifold 108d allows the flow of the refrigerant from the racks 112a-m to the evaporators 116a-i. Here, the refrigerant is routed into the evaporators, where it absorbs heat from the warmed coolant returning from the internal cooling system 104 of the data center 102. The multi-valve manifold 108e allows the flow of the refrigerant from the pumps 118a-k to the evaporators 116a-i. The multi-valve manifold 108e directs the refrigerant into the evaporators 116a-i, to enable the refrigerant to absorb heat from the coolant before circulating back to the internal cooling system 104. The multi-valve manifold 108f controls the refrigerant flow from the pumps 118a-k into the internal cooling system 104 of the data center 102 and vice versa. The multi-valve manifold 108f is an interface to the internal cooling system 104 to receive warmed coolant from the internal cooling system 104 and return cooled coolant to the internal cooling system 104.

Each multi-valve manifold 108a-f is in signal communication with the controller 160 using wired and/or wireless connections. The controller 160 may send electronic signals to each multi-valve manifold 108a-f to control the opening and closing of each valve within each manifold multi-valve manifold 108a-f according to the specific combination of components that is determined to be activated to provide cooling to the data center 102.

### Example Rack

FIG. 2 illustrates an example embodiment of one or more racks 112. As can be seen in FIG. 2, an array of racks 112 are shown in conjunction with other components of the cooling architecture 110. The rack 112 (e.g., any of the racks 112a-m of FIG. 1A) may be configured to house a supervisory controller 120, at least one compressor 130, at least one flash tank 132, at least one oil separator 134, at least one high pressure valve 136, and at least one accumulator 138, among other components. The internal components of each rack 112a-m are interconnected to control the operations of the rack and the refrigerant flow. The illustrated configuration of the rack 112 is exemplary. In other configurations, the rack 112 may include some of these components, additional components, and may be arranged in any suitable method to allow the refrigerant flow to provide cooling. The at least one compressor 130, at least one flash tank 132, at least one oil separator 134, at least one high pressure valve 136, and at least one accumulator 138 are fluidly connected to each other through refrigerant conduit subsystems 106 as shown by the arrows in FIG. 2.

In a rack 112, when it is activated, the refrigerant may flow from the multi-valve manifold 108c into the activated compressor(s) 130, where it is pressurized to a higher temperature and pressure. The refrigerant then flows from the compressor(s) 130 to the activated oil separator(s) 134, where oil mixed with the refrigerant is separated out and returned to the compressor(s). From the oil separator 134, the refrigerant flows to the multi-valve manifold 108a, where it is directed to the activated outdoor heat exchanger(s) 114a-n, where it releases heat to the surrounding environment. The refrigerant may then flow to the multi-valve manifold 108b, where it is directed to the activated high-pressure valve(s) 136 of the rack 112, where its pressure is reduced.

The refrigerant enters the activated flash tank(s) 132, where it is separated into liquid and vapor phases, with the liquid is accumulated at the bottom due to gravity and vapor rises to the top of the flash tank. The liquid refrigerant may flow from the flash tank 132 to the multi-valve manifold 108d, which directed it to the activated evaporator(s) 116a-i. The vapor refrigerant may flow from the flash tank 132 to the activated accumulator(s) 138 and then to the activated compress(s) 130. This cycle may continue until the cooling demand of the data center 102 is met.

### Example Supervisory Controller

One or more of the components of the rack 112 are controlled by the supervisory controller 120 and/or the controller 160. For example, the supervisory controller 120 may send electronic signals 129 to the compressors 130 to activate or deactivate them, or set their speed, in case of a variable-speed compressor 130. In some embodiments, the electronic signals 129 may be determined by the controller 160 and sent to the supervisory controller 120. In some embodiments, the electronic signals 129 may be determined by the supervisory controller 120. The supervisory controller 120 determines which combination of compressors 130 to be activated based on the received instructions from the controller 160 which is based on the cooling demand of the data center 102.

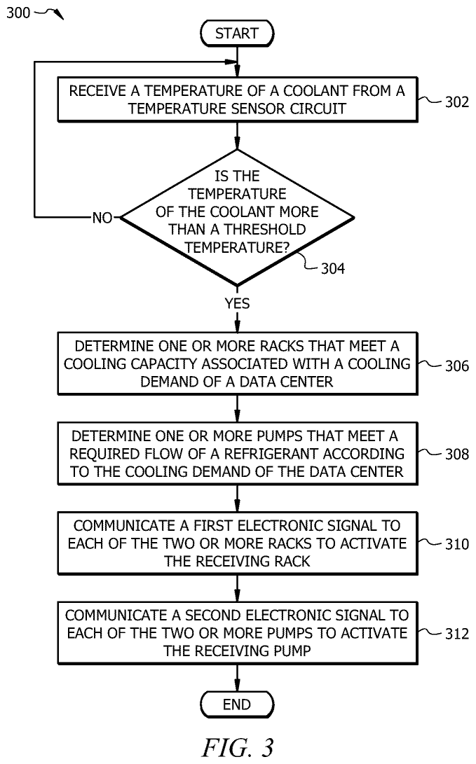

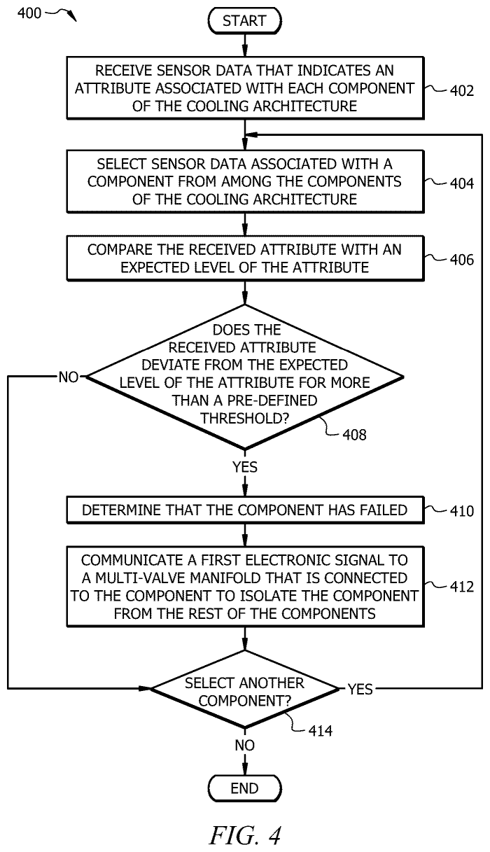

The supervisory controller 120 is communicatively coupled (e.g., via wired and/or wireless connection) to other components in the rack 112 and configured to control their operations. In some embodiments, supervisory controller 120 can be one or more controllers associated with one or more components of the rack 112. The supervisory controller 120 includes a processor 122 in signal communication with a memory 126 and an input/output (I/O) interface 124. The processor 122 comprises one or more processors. The processor 122 is any electronic circuitry including, but not limited to, state machines, one or more central processing unit (CPU) chips, logic units, cores (e.g., a multi-core processor), field-programmable gate arrays (FPGAs), application-specific integrated circuits (ASICs), graphic processing units (GPUs), or digital signal processors (DSPs) that communicatively couples to memory 126 and controls the operations of rack 112. The processor 122 may be a programmable logic device, a microcontroller, a microprocessor, or any suitable combination of the preceding. The processor 122 is communicatively coupled to, and in signal communication with, the memory 126. The one or more processors are configured to process data and may be implemented in hardware or software. For example, the processor 122 may be 8-bit, 16-bit, 32-bit, 64-bit or of any other suitable architecture. The processor 122 may include an arithmetic logic unit (ALU) for performing arithmetic and logic operations, processor registers that supply operands to the ALU and store the results of ALU operations, and a control unit that fetches instructions from memory 126 and executes them by directing the coordinated operations of the ALU, registers, and other components. The processor 122 may include other hardware and software that operate to process information, control the rack 112, and perform any of the functions described herein. The processor 122 may be configured to execute software instructions to perform operations of the supervisory controller 120. For example, the processor 122 may be configured to execute the software instructions 128 to cause the supervisory controller 120 to perform one or more of its operations described herein. The processor 122 may execute code/software instructions 128 to perform any of its operations. The processor 122 is not limited to a single processing device and may encompass multiple processing devices. The processor 122 may be configured to perform one or more operations of the supervisory controller 120 described in FIGS. 1A-1B and 2, one or more operations of the method 300 described in FIG. 3, and one or more operations of the method 400 described in FIG. 4.

The memory 126 may be a non-transitory computer-readable medium. The memory 126 includes one or more disks, tape drives, or solid-state drives, and may be used as an over-flow data storage device, to store programs when such programs are selected for execution, and to store instructions and data that are read during program execution. The memory 126 may be volatile or non-volatile and may comprise a read-only memory (ROM), random-access memory (RAM), ternary content-addressable memory (TCAM), dynamic random-access memory (DRAM), and static random-access memory (SRAM). The memory 126 is operable to store any suitable set of instructions, logic, rules, and/or code for executing the functions described in this disclosure. For example, the memory 126 may store and retrieve information corresponding to software instructions 128, electronic signals 129, and/or other data, instructions, and operating parameters for components in the system 100. The software instructions 128 may comprise any suitable set of instructions, logic, rules, or code operable to execute the processor 122 and perform the functions described herein, such as some or all of those described in FIGS. 1A-4. The electronic signals 129 may include signals to control the operations of any receiving component.

The I/O interface 124 is configured to communicate data and signals with other devices. For example, the I/O interface 124 may be configured to communicate electrical signals with the other components of the rack 112. The I/O interface 124 may comprise ports and/or terminals for establishing signal communications between the supervisory controller 120 and other devices. The I/O interface 124 may be configured to enable wired and/or wireless communications. Connections between various components of the rack 112 and between components of rack 112 may be wired or wireless.

In some embodiments, a wireless connection may be employed to provide at least some or all of the connections between components of the rack 112. In some embodiments, a data bus may couple various components of the rack 112 together such that data is communicated therebetween. In some embodiments, the data bus may include, for example, any combination of hardware, software embedded in a computer-readable medium, or encoded logic incorporated in hardware or otherwise stored (e.g., firmware) to couple components of the rack 112 to each other.

As an example and not by way of limitation, the data bus may include an accelerated graphics port (AGP) or other graphics bus, a controller area network (CAN) bus, a front-side bus (FSB), a hypertransport (HT) interconnect, an InfiniBand™ interconnect, a low-pin-count (LPC) bus, a memory bus, a micro channel architecture (MCA) bus, a peripheral component interconnect (PCI) bus, a PCI-Express (PCI-X) bus, a serial advanced technology attachment (SATA) bus, a video electronics standards association local bus (VLB), or any other suitable bus or a combination of two or more of these. In various embodiments, the data bus may include any number, type, or configuration of data buses, where appropriate. In certain embodiments, one or more data buses (which may each include an address bus and a data bus) may couple the supervisory controller 120 to other components of the rack 112.

### Example Compressor

The array of the compressors 130 may include one or more compressors. Each compressor may be a variable speed compressor or a multiple-stage compressor. Each compressor may be generally configured to compress (e.g., increase the pressure of) the refrigerant. Each compressor 130 may be a low-temperature compressor (for low-temperature applications) or a medium-temperature compressor (for medium-temperature applications). The compressors 130 are fluidly coupled with the refrigerant conduit subsystem 106 and may be positioned downstream of the evaporators via multi-valve manifold 108c. The compressors 130 are in signal communication with the supervisory controller 120 using wired and/or wireless connections. The supervisory controller 120 may communicate electronic signals to each compressor 130 to control its speed and to activate or deactivate it. A variable-speed compressor is generally configured to operate at different speeds to increase the pressure of the refrigerant to keep the refrigerant moving along the fluid conduit subsystem 106. In the variable-speed compressor configuration, the speed of compressor 130 can be modified to adjust the cooling capacity and/or load of the rack 112. Meanwhile, in the multi-stage compressor configuration, one or more compressors can be turned on or off to adjust the cooling capacity of the rack 112. In some embodiments, the supervisory controller 120 may control the speed of the compressor 130 via a variable speed drive component that is configured to translate electronic control signals into frequency adjustments (e.g., in terms of Hertz). For example, the variable speed drive component receives signals from the supervisory controller 120 to increase or decrease the frequency of the electrical power supplied to the compressor 130, which in turn regulates the compressor's speed. The variable speed drive may be a part of or communicatively coupled to the supervisory controller 120 and implemented by the processor 122 executing the software instructions 128 to perform its functions.

### Example Flash Tank

The array of flash tanks 132 may include one or more flash tanks. Each flash tank 132 may generally be a physical storage component configured to store refrigerant in vapor and liquid forms. The flash tank 132 is fluidly coupled to the refrigerant conduit subsystem 106 and is positioned downstream of the high-pressure valve 136. The flash tank 132 may be configured to separate the refrigerant into a vapor refrigerant and a liquid refrigerant. Typically, the vapor refrigerant collects near the top of the flash tank 132 and the liquid refrigerant is collected at the bottom of the flash tank 132. In some embodiments, during providing conditioning according to a conditioning demand, the liquid refrigerant flows from flash tank 132 toward the selected evaporators via the multi-valve manifold 108d. Additionally, the vapor refrigerant (gas) flows from the flash tank 132 toward the accumulator 138 and then the selected compressor(s) 130.

### Example Oil Separator

The array of oil separators 134 may include one or more oil separators. Each oil separator 134 is generally a physical component that is configured to separate oil from the refrigerant. The oil separator 134 may separate oil from the refrigerant discharged from the compressors 130 and return (or circulate) the separated oil back to the compressors 130. In some examples, the oil separator 134 may be a coalescing oil separator, centrifugal oil separator, or any other type. For example, the coalescing oil separator may include mesh-shaped filters to separate oil from the refrigerant to merge into larger oil droplets, which cannot pass through the mesh. In another example, the centrifugal oil separator separates the oil from the refrigerant by spinning the oil-refrigerant mixture to use the centrifuge force to cause the oil to move outward and be separated from the refrigerant. The oil separator 134 is fluidly coupled to the refrigerant conduit subsystem 106 and positioned downstream of the compressors 130. The oil separators 134 separate the oil from the refrigerant before it enters other downstream components. The oil may be introduced to certain components of the cooling system, such as the compressors 130 for lubrication of the interior of the compressors. In some occasions, the oil may be mixed with the refrigerant as it passes through the compressor. By separating out the oil, the efficiency of outdoor heat exchangers is maintained. If the oil separator 134 were not present, then the oil (mixed with the refrigerant) may clog any of the heat exchangers, which may reduce the refrigerant's ability to absorb or release heat in the heat exchangers, which leads to the heat transfer efficiency of system 100 being reduced.

### Example High Pressure Valve

The high-pressure valve 136 may be an expansion valve, a motorized valve, a solenoid valve, an EEV, a TXV, or any other suitable valve configured to control the flow of the refrigerant. The valve 136 is fluidly coupled with the refrigerant conduit subsystem 106 and positioned downstream of the multi-valve manifold 108d and the outdoor heat exchangers, and upstream of the flash tanks. The valve 136 is in signal communication with the supervisory controller 120 using wired and/or wireless connections. The valve 136 may be configured to receive the refrigerant discharged from the outdoor heat exchangers and reduce the pressure of the received refrigerant before it reaches the flash tank. The valve 136 may regulate the pressure of the refrigerant. In this process, the opening of the valve 136 may be adjusted to control the flow of the refrigerant and the pressure drop of the refrigerant as it transitions from the high-pressure side after the outdoor heat exchangers to the lower pressure in the flash tank. The valve 136 may have a throttle that can open or close to varying degrees to control the flow rate of the refrigerant. By narrowing the passage of the valve 136, the valve 136 increases resistance to the refrigerant flow rate, which causes an increase in the pressure drop. By opening the passage of the valve 136, the valve 136 reduces the resistance to the refrigerant flow rate, which reduces the pressure drop.

### Example Accumulator

Each accumulator 138 may be a physical storage configured to collect and store refrigerant vapor before it enters the compressors 130. Each accumulator 138 is fluidly coupled with the refrigerant conduit subsystem 106 and positioned downstream of the flash tank 132 and upstream of the compressor 130. Each accumulator 138 serves as a buffer to reduce the likelihood of liquid refrigerant from reaching the compressors. The accumulator 138 may separate any remaining liquid from the refrigerant vapor to allow vapor to flow toward the compressors 130. The accumulator 138 may be in signal communication with the supervisory controller 120 using wired and/or wireless connections.

### Example Outdoor Heat Exchanger

Referring back to FIG. 1A, the array of outdoor heat exchangers 114a-n may include two or more outdoor heat exchangers. Each outdoor heat exchanger is configured to transfer heat from the refrigerant into the surrounding outdoor environment. Each outdoor heat exchanger may generally include coils and fans to move air across the coils. When refrigerant flows through the coils, the outdoor heat exchangers remove heat from the refrigerant, and this allows the heat to be released into the outdoor environment. This process cools the refrigerant. The outdoor heat exchangers 114a-n are fluidly coupled to the refrigerant conduit subsystem 106 and are positioned downstream of the multi-valve manifold 108a and the compressors within the racks 112a-m, and upstream of high-pressure valves within the racks 112a-m via the multi-valve manifold 108b. The outdoor heat exchangers 114a-n are in signal communication with the controller 160 using wired and/or wireless connections. The controller 160 may send electronic signals to control the speed of the fans based on temperature conditions and cooling demand.

The outdoor heat exchangers 114a-n may be operated as condensers and/or gas coolers. When operating as a condenser, each outdoor heat exchanger cools the refrigerant such that the refrigerant changes from a gaseous state to a liquid state. When operating as a gas cooler, each outdoor heat exchanger cools the refrigerant in its gaseous form without a phase change. Each outdoor heat exchanger 114a-n may be positioned to discharge heat removed from the refrigerant into the surrounding air, for example, on a rooftop or an external wall of a building. This disclosure contemplates any suitable refrigerant (e.g., carbon dioxide) being used in the cooling architecture 110. The cooling architecture 110 may include any appropriate number of outdoor heat exchangers 114a-n, configured as described.

### Example Evaporator

The array of evaporators 116a-i may include two or more evaporators. Each evaporator may generally include one or more evaporator coils and/or brazed plate heat exchangers. The evaporators 116a-i are fluidly coupled to the refrigerant conduit subsystem 106 and are positioned downstream of the flash tanks of the racks 112a-m via multi-valve manifold 108d and upstream of the compressors via multi-valve manifold 108c. Each evaporator 116a-i is in signal communication with the controller 160 using wired and/or wireless connections. The controller 160 may send electronic signals to control the activation and deactivation of each evaporator based on temperature conditions and cooling demand.

Each evaporator 116a-i is configured to receive refrigerant from the configured flash tank(s) of the configured racks 112a-m. The refrigerant absorbs heat from the coolant (used by the internal cooling system 104 of the data center 102) that circulates around the coils. As the refrigerant flows through the coils, it cools the surrounding coolant (used by the internal cooling system 104 of the data center 102) in contact with the coils. This process lowers the temperature of the coolant and warms the refrigerant. The cooled coolant flows back into the internal cooling system 104 and the warmed refrigerant flows through the multi-valve manifold 108c to the configured rack(s) 112a-m.

### Example Pump

The array of pumps 118a-k may include one or more pumps. The number of pumps may correspond to the number of pipes/conduit subsystems 106 provided by the internal cooling system 104. Examples of pumps 118a-k may include centrifugal pumps, diaphragm pumps, magnetic drive pumps, and variable-speed pumps, among others. Each pump is configured to circulate coolant and/or refrigerant through the refrigerant conduit subsystem 106 to facilitate heat exchange from the refrigerant to the coolant (used by the internal cooling system 104) within the cooling architecture 110. Each pump 118a-k is fluidly coupled to the refrigerant conduit subsystem 106.

In some embodiments, the array of pumps 118a-k may be positioned at the inlet or suction line of the internal cooling system 104 and be configured to pump the coolant (after cooled by the refrigerant in the evaporator(s) 116a-i) into the internal cooling system 104. In such embodiment, the array of pumps 118a-k may be positioned downstream of the evaporators 116a-i (via a multi-valve manifold) and upstream of the internal cooling system 104 of the data center 102 (via a multi-valve manifold).

In some embodiments, the array of pumps 118a-k may be positioned at the outlet or the discharge line of the internal cooling system 104 and be configured to pump out the warmed coolant (after being circulated through the internal cooling system 104) from the internal cooling system 104 to the evaporators 116a-i. In such embodiments, the array of pumps 118a-k may be positioned downstream of the internal cooling system 104 of the data center 102 (via a multi-valve manifold) and upstream of the evaporators 116a-i (via a multi-valve manifold).

### Example Temperature Sensor Circuit

The temperature sensor circuit 142 may include one or more temperature sensing elements and circuitries. The temperature sensor circuit 142 may be implemented by a hardware circuit and configured to detect the temperature 184 of the target space that requires conditioning. The temperature sensor circuit 142 may include one or more temperature sensor circuit 142. The temperature sensor circuit 142 may include a thermocouple, a thermistor, a semiconductor-based temperature circuit board, or any other type of temperature sensor. In some examples, the temperature sensor circuit(s) 142 may be positioned upstream, downstream, and/or integrated within each component within the cooling architecture 110 to capture the temperature 184 of the refrigerant as it flows through the respective component and/or at any other location. For example, the temperature sensor circuit 142 may be placed at the inlet (suction line) and/or outlet (discharge line) of each outdoor heat exchanger 114a-n, each rack 112a-m, each internal components of each rack, each evaporator 116a-i, and each pump 118a-k to monitor temperature changes associated with each component.

The temperature sensor circuit 142 may be attached to a surface and/or the respective component using any appropriate means (e.g., threaded connections, clamps, adhesives, or the like). The temperature sensor circuit 142 is configured to detect the temperature 184 of the refrigerant periodically (e.g., every second, every minute, etc.) and/or on demand (e.g., in response to a request from a user provided to the controller 160 or a control panel). The temperature sensor circuit 142 is in signal communication with the controller 160 using wired and/or wireless connections. The temperature sensor circuit 142 may provide the detected temperature data (which includes the detected temperature 184) to the controller 160. The controller 160 may use the temperature data to evaluate the component operational conditions, e.g., whether it is failed or is about to fail. This process is described further below in conjunction with the operational flow of the cooling system 100 in greater detail.

### Example Pressure Sensor Circuit

The pressure sensor circuit 144 may include one or more pressure sensing elements and circuitries. The pressure sensor circuit 144 may be implemented by a hardware circuit and configured to detect the pressure 186 of the refrigerant as it flows through various components of the cooling architecture 110. The pressure sensor circuit 144 may include one or more types of pressure sensor circuits, such as piezoelectric sensors, strain gauge sensors, capacitive pressure sensors, or any other suitable pressure sensors. In some embodiments, the pressure sensor circuit 144 may be positioned upstream, downstream, and/or integrated within each component within the cooling architecture 110 to capture the pressure 186 of the refrigerant as it enters and/or exits a component and/or at any other location. For example, the pressure sensor circuit 144 may be placed at the inlet (suction line) and/or outlet (discharge line) of each outdoor heat exchanger 114a-n, each rack 112a-m, each internal component of each rack, each evaporator 116a-i, and each pump 118a-k to monitor pressure changes associated with each component.

The pressure sensor circuit 144 may be attached to a surface and/or the respective component using any appropriate means (e.g., threaded connections, clamps, adhesives, or the like). The pressure sensor circuit 144 is configured to detect the pressure 186 of the refrigerant periodically (e.g., every second, every minute, etc.) and/or on demand (e.g., in response to a request from a user provided to the controller 160 or a control panel). The pressure sensor circuit 144 is in signal communication with the controller 160 using wired and/or wireless connections. The pressure sensor circuit 144 may provide the detected pressure data (which includes the detected pressure 186) to the controller 160. The controller 160 may use the pressure data to evaluate the component operational conditions, e.g., whether it is failed or is about to fail. This process is described further below in conjunction with the operational flow of the cooling system 100 in greater detail.

### Example Voltage Sensor Circuit

The voltage sensor circuit 146 may include one or more voltage sensing element and circuitries. The voltage sensor circuit 146 may be implemented by a hardware circuit and configured to detect the voltage levels 188 of each component within the cooling architecture 110. The voltage sensor circuit 146 may include one or more types of voltage sensor circuits, such as resistive voltage sensors, capacitive voltage sensors, or any other suitable voltage sensors. In some embodiments, the voltage sensor circuit 146 may be positioned adjacent to, integrated within, or associated with each component to capture the voltage levels 188 of each internal component of each and/or at any other relevant location. For example, the voltage sensor circuit 146 may be integrated within and/or placed adjacent to each outdoor heat exchanger 114a-n, each rack 112a-m, each internal component of each rack (such as each compressor, etc.), each evaporator 116a-i, and each pump 118a-k to monitor the voltage levels 188 associated with each component.

The voltage sensor circuit 146 may be attached to a surface and/or associated with the respective component using any appropriate means (e.g., threaded connections, clamps, adhesives, or the like). The voltage sensor circuit 146 is configured to detect the voltage level 188 of each component periodically (e.g., every second, every minute, etc.) and/or on demand (e.g., in response to a request from a user provided to the controller 160 or a control panel). The voltage sensor circuit 146 is in signal communication with the controller 160 using wired and/or wireless connections. The voltage sensor circuit 146 may provide the detected voltage data (which includes the detected voltage levels 188) to the controller 160. The controller 160 may use the voltage data to evaluate the operational conditions of each component, e.g., whether it is failed or is about to fail. This process is described further below in conjunction with the operational flow of the cooling system 100 in greater detail.

### Example Visual Indicator

The visual indicator 150 may include one or more types of visual signaling devices configured to provide a visual status of each component within the cooling architecture 110. The visual indicator 150 may be implemented by a hardware circuit and may include various types of signaling devices, such as light-emitting diodes (LEDs), light bulbs, status lights, or display panels, among others. In some embodiments, the visual indicator 150 may include speakers configured to sound an alarm. In some embodiments, the visual indicator 150 may be positioned adjacent to each component. For example, the visual indicator 150 may be placed adjacent to each outdoor heat exchanger 114a-n, each rack 112a-m, each evaporator 116a-i, and each pump 118a-k to indicate the component's operational status. In some embodiments, the visual indicator 150 may change colors (e.g., green, yellow, red), display different signals, and/or sound an alarm based on the condition of the component—such as normal operation (indicated by green color), maintenance needed (indicated by yellow color), or failure (indicated by red color). In some embodiments, the visual indicator 150 may change between flashing and constant light, where one of these configurations (e.g., flashing or constant light) indicates a failure or maintenance needed, and the other indicates an operational component. In some embodiments, a different pattern for flashing light may be used to differentiate between a failure and maintenance needed scenarios for each component.

The visual indicator 150 is in signal communication with the controller 160 using wired and/or wireless connections. In response to detecting a failure or an anomalous condition in a given component, the controller 160 may send an electronic signal to the visual indicator 150 to adjust its status. For example, upon detecting a failure, the controller 160 may instruct the visual indicator 150 to change to a red status.

### Example Controller

FIG. 1B illustrates an example embodiment of the controller 160 of the cooling system 100 (see FIG. 1A). The controller 160 is communicatively coupled (e.g., via wired and/or wireless connection) to other components in the cooling system 100 and configured to control their operations. In some embodiments, controller 160 can be one or more controllers associated with one or more components of the cooling system 100. The controller 160 includes a processor 162 in signal communication with a memory 166 and an I/O interface 164. The processor 162 comprises one or more processors. The processor 162 is any electronic circuitry including, but not limited to, state machines, one or more CPU chips, logic units, cores (e.g., a multi-core processor), FPGAs, ASICs, or DSPs that communicatively couples to memory 166 and controls the operation of cooling system 100. The processor 162 may be a programmable logic device, a microcontroller, a microprocessor, or any suitable combination of the preceding. The processor 162 is communicatively coupled to, and in signal communication with, the memory 166. The one or more processors are configured to process data and may be implemented in hardware or software. For example, the processor 162 may be 8-bit, 16-bit, 32-bit, 64-bit or of any other suitable architecture. The processor 162 may include an ALU for performing arithmetic and logic operations, processor registers that supply operands to the ALU and store the results of ALU operations, and a control unit that fetches instructions from memory 166 and executes them by directing the coordinated operations of the ALU, registers, and other components. The processor 162 may include other hardware and software that operates to process information, control the cooling system 100, and perform any of the functions described herein. The processor 162 may be configured to execute software instructions to perform operations of the controller 160. For example, the processor 162 may be configured to execute the software instructions 168 to cause the cooling system 100 to perform one or more of its operations described herein. The processor 162 may execute code/software instructions 168 to perform any of its operations. The processor 162 is not limited to a single processing device and may encompass multiple processing devices. The processor 162 may be configured to perform one or more operations of the controller 160 described in FIGS. 1A to 4, one or more operations of the operational flow of the cooling system 100, one or more operations of the method 300 described in FIG. 3, and one or more operations of the method 400 described in FIG. 4.

The memory 166 may be a non-transitory computer-readable medium. The memory 166 includes one or more disks, tape drives, or solid-state drives, and may be used as an over-flow data storage device, to store programs when such programs are selected for execution, and to store instructions and data that are read during program execution. The memory 166 may be volatile or non-volatile and may comprise a ROM, RAM, TCAM, DRAM, and SRAM. The memory 166 is operable to store any suitable set of instructions, logic, rules, and/or code for executing the functions described in this disclosure. For example, the memory 166 may store and retrieve information corresponding to software instructions 168, electronic signals 170a-c, 196, 198, temperature data 172, operational status data 152, scheduling protocol 154, an available power level 156, a threshold power level 158, threshold temperature 176a, threshold temperature 176b, expected levels 192, predefined threshold 194, configuration algorithm 180, sensor data 190, and/or other data, instructions, and operating parameters for components in the system 100. The software instructions 168 may comprise any suitable set of instructions, logic, rules, or code operable to execute the processor 162 and perform the functions described herein, such as some or all of those described in FIGS. 1A-4. The electronic signals 170a-c, 196, 198, may include signals to control the operations of any receiving component.

The configuration algorithm 180 may be implemented by the processor 162 executing the software instructions 168 and is generally configured to determine a more optimal configuration of components within the cooling architecture 110 to activate or adjust to meet the cooling demand of the data center 102 and deactivate the rest of the components. The operations of the configuration algorithm 180 are described further below. In brief, the configuration algorithm 180 may adjust the active components based on fluctuations in the cooling demand, available power or energy resources, refrigerant temperature, and/or coolant temperature, among others to maintain the operation of the cooling architecture 110 and adapt to any of these fluctuations.

The I/O interface 164 is configured to communicate data and signals with other devices. For example, the I/O interface 164 may be configured to communicate electrical signals with the other components of the cooling systems 100. The I/O interface 164 may comprise ports and/or terminals for establishing signal communications between the controller 160 and other devices. The I/O interface 164 may be configured to enable wired and/or wireless communications. Connections between various components of the cooling system 100 and between components of system 100 may be wired or wireless. For example, conventional cables and contacts may be used to couple the controller 160 to various components of the cooling system 100.

In some embodiments, a wireless connection may be employed to provide at least some or all of the connections between components of the cooling system 100. In some embodiments, a data bus may couple various components of the cooling system 100 together such that data is communicated therebetween. In some embodiments, the data bus may include, for example, any combination of hardware, software embedded in a computer-readable medium, or encoded logic incorporated in hardware or otherwise stored (e.g., firmware) to couple components of the cooling system 100 to each other.

As an example, and not by way of limitation, the data bus may include an GP or other graphics bus, a CAN bus, a FSB, a HT interconnect, an InfiniBand™ interconnect, a LPC bus, a memory bus, an MCA bus, a PCI bus, a PCI-X bus, a SATA bus, a VLB, or any other suitable bus or a combination of two or more of these. In various embodiments, the data bus may include any number, type, or configuration of data buses, where appropriate. In certain embodiments, one or more data buses (which may each include an address bus and a data bus) may couple the controller 160 to other components of the cooling system 100.

### Operational Flow of the Cooling System

In operation, the cooling system 100 may initiate its operation in response to detecting that the temperature of the coolant does not meet the cooling demand of the data center 102. In this process, the controller 160 may monitor and receive temperature data 172a from the temperature sensor circuit 140a which is positioned adjacent to a refrigerant conduit subsystem 106 connected to the data center 102. For example, the controller 160 may monitor and receive temperature data 172a periodically (e.g., every second, every minute, etc.), in real-time, or on-demand. In response, the controller 160 (e.g., via the configuration algorithm 180) may determine whether the received temperature data 172a indicates that the temperature of the coolant (used by the internal cooling system 104) is more than a threshold temperature 176, where the threshold temperature is associated with the cooling demand of the data center 102.

In response to determining that the received temperature data 172a from the temperature sensor circuit 140a is more than the threshold temperature 176, the controller 160 (e.g., via the configuration algorithm 180) may trigger a sequence of control operations to adapt to the change in the coolant temperature and the current cooling demand of the data center 102. The controller 160 (e.g., via the configuration algorithm 180) may evaluate the capacity of the racks 112a-m to determine which of the racks have the cooling capacity to reduce the coolant temperature down to the desired or target threshold temperature 176.

### Configuring Racks

In some embodiments, the controller 160 (e.g., via the configuration algorithm 180) may configure (e.g., activate) any number of racks 112a-m. For example, the controller 160 may determine a rack 112a-m that meets the new cooling capacity associated with the current cooling demand of the data center 102. In another example, the controller 160 may determine two or more rack(s) 112a-m that, in the aggregate, meet the new cooling capacity associated with the current cooling demand of the data center 102. In response, the controller 160 may communicate a first electronic signal 170a to each of the configured rack(s) 112a-m to activate it/them. The first electronic signal 170a may activate the receiving rack(s) 112a-m. The activated rack, in turn, may determine which combination of compressor(s) to activate to meet the current cooling demand of the data center 102. For example, the activated rack 112 (via the supervisory controller 120 (see FIG. 2)) may send electronic signals 129 to the identified compressor(s) 130. Upon receiving the electronic signals 129 from the supervisory controller 120, the selected compressor(s) 130 may activate and begin pressurizing the refrigerant to a required level to meet the cooling demand. When the compressor(s) 130 activate, they pull refrigerant from the flash tank within the rack and compress the refrigerant into a higher temperature and pressure. In response, the refrigerant may circulate within the components of the rack, similar to that described in FIG. 2 to cool the refrigerant, dissipate its heat to the outdoors, and facilitate heat transfer from the coolant of the internal cooling system 104 to the refrigerant within the configured evaporator(s) 116a-i.

### Configuring Pumps

The controller 160 (e.g., via the configuration algorithm 180) may determine which combination of pumps 18a-k are required to meet the flow rate of the refrigerant at inlet of the data center 102 according to the current cooling demand of the data center, to adapt to the change to the current cooling demand of data center 102. To this end, the controller 160 may evaluate the operational status and capacity of each pump 114a-k to determine which combination of pumps 114a-k have the capacity to meet the required flow rate for the refrigerant.

In some embodiments, the controller 160 (e.g., via the configuration algorithm 180) may configure (e.g., activate) any number of pumps 114a-k. For example, the controller 160 may determine a pump 114a-k that meets the new flow rate requirement for the refrigerant. In another example, the controller 160 may determine two or more pumps 114a-k that, in the aggregate, meet the new required flow rate of the refrigerant. In response, the controller 160 may communicate a second electronic signal 170b to the selected pump(s) 114a-k to activate them/it. The second electronic signal 170b may activate the receiving pump(s) 114a-k.

### Configuring a Combination of Components

The controller 160 (e.g., via the configuration algorithm 180) may determine which combination of components (e.g., evaporators 116a-i, outdoor heat exchangers 114a-n, racks 112a-m, and pumps 118a-k) to activate and route the refrigerant. For example, the controller 160 may evaluate the cooling demand of the data center 102 and configure (e.g., activate) one or more evaporators 116a-i that, in the aggregate, meet the new cooling capacity required to transfer heat from the coolant such that the detected temperature 174 corresponds to the threshold temperature 176. The controller 160 may communicate an electronic signal to each configured evaporator 116a-i to activate them so they transfer heat from the coolant to the refrigerant.

The controller 160 (e.g., via the configuration algorithm 180) may determine which outdoor heat exchangers 114a-n are needed to dissipate the absorbed heat from the refrigerant to the outdoor environment. The controller 160 (e.g., via the configuration algorithm 180) may configure (e.g., activate) outdoor heat exchangers 114a-n, that in the aggregate, dissipate the absorbed heat from the refrigerant to the outdoor environment to meet the new cooling demand of the data center 102. Based on the cooling demand, the controller 160 may send an electronic signal to each configured (e.g., activate) outdoor heat exchanger 114a-n to activate them to enable the refrigerant to release its absorbed heat to the outdoor environment.

The controller 160 (e.g., via the configuration algorithm 180) may configure (e.g., activate) the racks 112a-m that, in the aggregate, provide the required cooling capacity, similar to that described above. The controller 160 (e.g., via the configuration algorithm 180) may configure (e.g., activate) the pumps 118a-k that, in the aggregate, provide the new desired refrigerant flow rate at the inlet of the data center 102, similar to that described above.

In response to these configurations (e.g., activations), the controller 160 may communicate an electronic signal 170c to each multi-valve manifold 108a-f to provide instructions to at least partially open the valves to the selected components and close the valves to the non-selected components. In this way, the refrigerant flows only through the configured components.

In response, the refrigerant may circulate through the selected rack(s) 112a-m, selected compressor(s), selected evaporator(s) 116a-i, and selected outdoor heat exchanger(s) 114a-n. This process may continue until the temperature 174 of the coolant corresponds to the desired threshold temperature 176.

### Responding to Fluctuations in Cooling Demand and Available Power

In some embodiments, the controller 160 (e.g., via the configuration algorithm 180) may adjust the configuration, the number of active components, the flow path of the refrigerant through the cooling architecture 110 to respond to any fluctuations or changes in the cooling demand of the data center 102, in available power or energy resources, temperature, among others.

In some embodiments, the inlet temperature of the coolant (captured by the temperature sensor circuit 140a) may be used to determine whether the number, combination, and/or operations of the compressors need to be adjusted to meet the changes (e.g., increase or decrease) in the cooling demand of the data center 102. In this process, the controller 160 may receive and monitor temperature 174a from the temperature sensor circuit 140a which is positioned at the inlet of the internal cooling system 104. If it is determined that the inlet temperature of the coolant has deviated from the threshold temperature 176a, the controller 160 (e.g., via the configuration algorithm 180) may determine that the cooling demand has changed (e.g., increased or decreased). In response, the controller (e.g., via the configuration algorithm 180) may adjust the configuration and/or operation of one or more active components to respond to the detected change in the cooling demand. For example, if it is determined that the inlet temperature of the coolant has become more than the threshold temperature 176a, the controller 160 (e.g., via the configuration algorithm 180) may add additional rack(s) 112a-m in order to activate additional compressor(s), increase the load (e.g., speed) of the currently active compressor(s), among others, to meet the increase in the cooling demand. The controller 160 may communicate electronic signals 170a to the supervisory controller 120 (see FIG. 2) to activate additional compressor(s) and/or increase the load (e.g., speed) of the currently active compressor(s). In response, the now active supervisory controller may communicate electronic signals 129 (see FIG. 2) to the configured compressor(s) to initiate operation of the additional compressor(s) and/or adjust the load (e.g., speed) of the currently active compressor(s) as needed. In some cases, the increase in the cooling demand may be in response to the increase in the processing load of the data center 102, e.g., during peak operational hours, among others.

In another example, if it is determined that the inlet temperature of the coolant has become less than the threshold temperature 176a, the controller 160 (e.g., via the configuration algorithm 180) may selectively deactivate one or more rack(s) 112a-m to adjust the load of the currently active compressor(s) and/or deactivate some of the currently active compressor(s) to decrease the cooling capacity in response to the reduced cooling demand. The controller 160 may communicate electronic signals 170a to the supervisory controller 120 within the selected rack(s) to either deactivate certain compressor(s) or reduce their load (e.g., speed) as required according to the reduced cooling demand. In response to receiving the electronic signals 170a, the now active supervisory controller(s) 120 may communicate electronic signals 129 to the selected compressor(s) 130 within the rack(s), to instruct them to adjust their speed or to deactivate them. In some cases, the decrease in the cooling demand may be in response to the decrease in the processing load of the data center 102, e.g., during off-peak operational hours, among others. This also prevents overcooling the data center 102 and conserves excess energy.

In some embodiments, one or more compressors may be activated, one or more compressors may be deactivated, the speed of one or more compressors may be increased, the speed of one or more compressors may be decreased to respond to the detected change in the cooling demand of the data center 102. In this way, the controller 160 may respond dynamically to changes and fluctuations in the inlet temperature and cooling demand.

In some embodiments, the outlet temperature of the coolant (captured by the temperature sensor circuit 140b) may be used to determine whether the number, combination, and/or operations of the pumps 118a-k need to be adjusted to maintain the desired coolant flow rate according to the changes in the cooling demand of the data center 102. In this process, the controller 160 may receive and monitor temperature data 174b from the temperature sensor circuit 140b, which is positioned at the outlet of the internal cooling system 104. If it is determined that the outlet temperature of the coolant has deviated from the threshold temperature 176b, the controller 160 (e.g., via the configuration algorithm 180) may determine that the coolant flow rate needs adjustment due to changes in the cooling demand. In response, the controller 160 (e.g., via the configuration algorithm 180) may adjust the configuration and/or operation of one or more pumps 118a-k to respond to the detected change in the coolant flow rate requirements. For example, if it is determined that the outlet temperature of the coolant has become more than the threshold temperature 176b, the controller 160 (e.g., via the configuration algorithm 180) may add additional pump(s) 118a-k or increase the load (e.g., speed) of the currently active pump(s) to increase the coolant flow rate and meet the increase in the flow rate to accommodate the increase in the cooling demand. The controller 160 may communicate electronic signals 170b to the selected pump(s) 118a-k to activate additional pump(s) and/or increase the load (e.g., speed) of the currently active pump(s). In response, the receiving pump(s) 118a-k may initiate or adjust their operations to circulate the coolant at an increased flow rate to respond to the increase in outlet temperature. In some cases, the increase in the coolant flow rate may be in response to an increased cooling demand caused by higher processing loads of the data center 102, such as during peak operational hours, etc.

In another example, if it is determined that the outlet temperature of the coolant has become less than the threshold temperature 176b, the controller 160 (e.g., via the configuration algorithm 180) may selectively deactivate one or more pump(s) 118a-k and/or reduce the load (e.g., speed) of the currently active pump(s) to decrease the coolant flow rate in response to a reduction in the cooling demand. The controller 160 may communicate electronic signals 170b to the selected pump(s) 118a-k to either deactivate them or adjust their load (e.g., speed) as required to achieve the reduced coolant flow rate. This prevents overcooling the data center 102 and conserves excess energy. In some cases, the decrease in coolant flow rate may be due to a reduction in the processing load within the data center 102, such as during off-peak operational hours.

In some embodiments, one or more pumps may be activated, one or more pumps may be deactivated, the speed of one or more pumps may be increased, and/or the speed of one or more pumps may be decreased to respond to the detected changes in cooling demand based on outlet temperature. In this way, the controller 160 dynamically manages the coolant flow rate in response to fluctuations in the outlet temperature and cooling demand.

In some embodiments, the controller 160 may perform similar operations to adjust the configuration, number of active components, the flow path of the refrigerant through the cooling architecture 110 to respond to changes in the available power resources (e.g., available power level 156) associated with the data center 102. The controller 160 may detect the available power resources based on the detected power level that is measured (e.g., by electrical probes) traversing through power cables connected to the cooling architecture 110 and/or data center 102, that transmit electrical power signals to the cooling architecture 110 and/or data center 102, respectively. For example, if it is determined that the available power has become less than a threshold power level 158, the controller 160 (e.g., via the configuration algorithm 180) may selectively deactivate one or more rack(s) 112a-m, pump(s) 118a-k, and/or other components to reduce the energy consumed by the cooling architecture 110, while still maintaining a stable cooling to the data center 102. In response, the controller 160 may send electronic signals to deactivate certain compressor(s) within the selected rack(s) and/or reduce the speed or deactivate specific pump(s) and/or other components as necessary to reduce the overall energy consumed by the cooling architecture 110.

In some embodiments, the controller 160 (e.g., via the configuration algorithm 180) may determine which components to activate, deactivate, or adjust (e.g., increase or decrease the load or speed) based on sensor data 190 from temperature sensor circuits 142, pressure sensor circuits 144, and voltage sensor circuits 146. Based on the sensor data 190, the controller 160 (e.g., via the configuration algorithm 180) may determine which component(s) are candidates (e.g., have the capacity, available unutilized load, speed, etc.) to respond to the detected fluctuation in cooling demand and/or available power or energy resources.

When a deviation (e.g., for more than a threshold range, such as more than 5 degrees, 6 degrees, etc.) is detected in the inlet or outlet temperature of the coolant, or if there is a change in available power resources (e.g., for more than a threshold range, such as more than a 10%, 20%, etc. from the baseline available power resources), the controller 160 (e.g., via the configuration algorithm 180) evaluates the currently implemented configuration of components and the status of each component, including the racks 112a-m, outdoor heat exchangers 114a-n, evaporators 116a-i, and pumps 118a-k. Based on the detected deviation in temperature and/or change in the available power resources, the controller 160 (e.g., via the configuration algorithm 180) may activate additional component(s) to increase cooling capacity, deactivate certain component(s) to conserve energy, or adjust the load of one or more active component(s) (e.g., by modifying speeds or pump flow rates).

In some embodiments, the controller 160 may monitor and respond to the available power level 156 associated with the data center 102. For example, the controller 160 may monitor the available power level periodically (e.g., every second, every minute, etc.), in real-time, or on-demand. In response to obtaining the available power level, the controller 160 may determine if the available power has depleted less than a threshold power level 158. The threshold power level 158 may be a 10%, 20%, etc. from the baseline available power, and adaptive to the changes in the energy usage consumption patterns by the data center 102 and/or the cooling architecture 110. If it is determined that the available power level 156 has depleted less than the threshold power level 158, the controller 160 may communicate an electronic signal to one or more components of the cooling architecture 110 to adjust the runtime and/or the load of each affected component to accommodate the reduction in the available power level. The electronic signal may cause the runtime of each of the affected one or more components is adjusted to maintain the cooling capacity associated with the cooling demand of the data center 102, while operating within the constraints of the reduced available power or energy resources.

In some embodiments, the controller 160 may receive and monitor operational status data 152 from each component of the cooling architecture 110. For example, the controller 160 may monitor and receive the operational status data 152 periodically (e.g., every second, every minute, etc.), in real-time, or on-demand. The operational status data 152 may indicate the load carried by each respective component. In response, the controller 160 may determine a scheduling protocol 154 for managing the activation and deactivation cycles (e.g., runtime) of each component. The scheduling protocol 154 may include a schedule of runtime for each component. In some embodiments, the scheduling protocol 154 may be determined such that the overall load is distributed substantially evenly across the plurality of components, to balance their usage and load.

### Detecting and Mitigating a Component Failure

In some embodiments, the controller 160 may detect and mitigate a failure of each component of the cooling architecture 110. Each component of the cooling architecture 110 may be associated with and/or connected to a temperature sensor circuit 142, a pressure sensor circuit 144, and a voltage sensor circuit 146. The controller 160 may receive and monitor the sensor data 190 received from the sensor circuits, including temperature sensor circuits 142, pressure sensor circuits 144, and voltage sensor circuits 146. For example, the controller 160 may monitor and receive the sensor data 190 periodically (e.g., every second, every minute, etc.), in real-time, or on-demand. The sensor data 190 may indicate attributes 182 of each component, where the attributes 182 may include temperature 184 of the refrigerant, pressure 186 of the refrigerant, and/or the voltage levels 188 of the internal components of the each given component.

In response to receiving the sensor data 190, the controller 160 (e.g., via the configuration algorithm 180) may compare each attribute 182 of each component to the counterpart historical or baseline level (e.g., the expected level 192) for each attribute associated with that component. For example, the controller 160 may compare the current temperature 184 of the refrigerant at a given component with an expected temperature level, the current pressure 186 of the refrigerant with an expected pressure level, and/or the current voltage level 188 at the component with an expected voltage level. Each expected level 192 may represent historically maintained values for each attribute associated with the normal operation of the component.

In response, the (e.g., via the configuration algorithm 180) may determine whether the component has failed based on the comparison. For example, if the controller 160 determines that an attribute 182 deviates from its respective expected level 192 by more than a predefined threshold 194, the controller 160 may determine that the associated component has failed. For example, if the temperature 184 of the refrigerant, pressure 186 of the refrigerant, or voltage level 188 at a first component deviates from its expected level by more than a predefined threshold 194, the controller 160 may determine that the first component has failed.

In response to determining that a component has failed, the controller 160 may communicate a first electronic signal 196 to multi-valve manifolds 108a-f connected to the failed component to isolate the failed component from the rest of the plurality of components. The first electronic signal 196 may cause the valve that allows the refrigerant flowing into the failed component to be closed and the valve that allow the flow of the refrigerant flowing out of the failed component to be closed. The controller 160 may also communicate an electronic signal to the failed component to turn off or deactivate the failed component. This leads to the failed component to be taken out of the operation until its failure is addressed and repaired.

To replace for the failed component, the (e.g., via the configuration algorithm 180) may identify and activate a counterpart component to take over the operation of the failed component. The term ‘counterpart component’ may refer to a component within the cooling architecture 110 that performs the same or a similar function as the failed component and is capable of taking over its operation. For example, if the failed component is an evaporator 116a-i, then its counterpart component would also be an evaporator that can manage the heat exchange required for cooling the coolant. Similarly, if the failed component is a compressor, a pump, an outdoor heat exchanger, a valve, etc., then the counterpart component is of that type of the failed component.

In some embodiments, the controller 160 may communicate a second electronic signal 198 to the selected counterpart component to activate it, where the second electronic signal 198 activates the selected counterpart component. The controller 160 may also send a third electronic signal 196 to the multi-valve manifolds 108a-f connected to the counterpart component to cause the multi-valve manifolds to at least partially open a valve that allows refrigerant to flow into the activated counterpart component, and to least partially open a valve that allows the refrigerant to flow out of the activated counterpart component. The controller 160 may also communicate an electronic signal to turn on or activate the counterpart component.

In some embodiments, if the cooling demand cannot be met by a single counterpart component, the (e.g., via the configuration algorithm 180) may identify two or more counterpart components to share the load of the failed component and to take over the operation of the filed component. To this end, the controller 160 may communicate a fourth electronic signal 198 to each identified counterpart component to activate each one to handle a portion of the load, where the fourth electronic signal 198 activates each receiving counterpart component. For example, the controller 160 may communicate a fifth electronic signal 196 to the multi-valve manifold(s) 108a-f connected to each counterpart component to cause the manifolds to at least partially open the valves that allow refrigerant to flow into each of these activated components, and to least partially open the valves that allow the refrigerant to flow out of the each now activated counterpart component. The fifth electronic signal 196 may cause each of the two or more valves to be at least partially opened. In other words, the (e.g., via the configuration algorithm 180) may trigger two or more valves that allow the refrigerant to flow into a respective component from among the two or more counterpart components to be at least partially opened and to trigger two or more valves that allow the refrigerant to flow out of a respective component from among the two or more counterpart components. In this way, the controller 160 may dynamically detect and mitigate component failures by isolating the failed component and activating a counterpart component, or multiple counterpart components, to maintain the cooling capacity of the cooling system 100 and to meet the current cooling demand of the data center 102.

In some embodiments, the controller 160 may change the status of a visual indicator 150 located adjacent to the failed component to indicate its failure. For example, when the controller 160 determines that a rack 112a-m, an evaporator 116a-i, compressor within one of the racks 112a-m, or any other component has failed (e.g., based on deviations in temperature, pressure, or voltage levels), the controller 160 may communicate an electronic signal to a visual indicator 150 located adjacent to the failed compressor. In response, the visual indicator 150 may change color, display an alert message, produce an alarm sound, etc. to indicate the failure at the component.

### Example Method for Adaptive Configuration of Components According to a Cooling Demand of a Physical Space

FIG. 3 illustrates a flowchart of an example method 300 of operating the system 100 of FIG. 1A for adaptive configuration of components according to a cooling demand of a physical space. The method 300 may be performed by the controller 160 (see FIGS. 1A-1B) when one or more processors (e.g., processor 162 of FIG. 1B) execute software instructions (e.g., software instructions 168 of FIG. 1B) stored in one or more memories (e.g., memory 166 of FIG. 1B). The method 300 may include operations 302-314. Modifications, additions, or omissions may be made to method 300. Method 300 may include more, fewer, or other operations. For example, operations may be performed in parallel or in any suitable order.

At operation 302, the controller 160 may receive a temperature of the coolant (that is used by the internal cooling system 104) from a temperature sensor circuit (e.g., temperature sensor circuit 140a and/or 140b), similar to that described in FIG. 1A.

At operation 304, the controller 160 may determine whether the temperature of the coolant is more than the threshold temperature, similar to that described in FIG. 1A. If it is determined that the temperature of the coolant is more than (e.g., greater than) the threshold temperature (‘Yes’), the method 300 may proceed to operation 306. Otherwise (‘No’), the method 300 may return to operation 302 to continue monitoring the temperature of the coolant.

At operation 306, the controller 160 may determine one or more racks 112a-m that meet the cooling capacity associated with the cooling demand of the data center 102, similar to that described in FIG. 1A.

At operation 308, the controller 160 may determine one or more pumps 118a-k that meet a required flow of the refrigerant according to the cooling demand of the data center 102, similar to that described in FIG. 1A.

At operation 310, the controller 160 may communicate a first electronic signal 170a to each of the one or more racks to activate the receiving rack, similar to that described in FIG. 1A.

At operation 312, the controller 160 may communicate a second electronic signal 170b to each of the one or more pumps to activate the receiving pump, similar to that described in FIG. 1A.

### Example Method for Detecting and Mitigating a Component Failure

FIG. 4 illustrates a flowchart of an example method 400 of operating the system 100 of FIG. 1A for detecting and mitigating a component failure. The method 300 may be performed by the controller 160 (see FIG. 1A-1B) when one or more processors (e.g., processor 162 of FIG. 1B) execute software instructions (e.g., software instructions 168 of FIG. 1B) stored in one or more memories (e.g., memory 166 of FIG. 1B). The method 400 may include operations 402-416. Modifications, additions, or omissions may be made to method 400. Method 400 may include more, fewer, or other operations. For example, operations may be performed in parallel or in any suitable order.

At operation 402, the controller 160 may receive sensor data 190 that indicates an attribute 182 associated with each component of the cooling architecture 110.

At operation 404, the controller 160 may select sensor data 190 associated with a component from among the components of the cooling architecture 110.

At operation 406, the controller 160 may compare the received attribute 182 with an expected level 192 of the attribute.

At operation 408, the controller 160 may determine whether the received attribute 182 deviates from the expected level 192 of the attribute for more than a pre-defined threshold 194. If it is determined that the received attribute 182 deviates from the expected level 192 of the attribute for more than (e.g., greater than) the pre-defined threshold 194 (‘Yes’), the method 400 may proceed to operation 410. Otherwise (‘No’), the method 400 may proceed to operation 414.

At operation 410, the controller 160 may determine that the component has failed.

At operation 412, the controller 160 may communicate a first electronic signal to a multi-valve 108a-f that is connected to the component to isolate the component from the rest of the components.

At operation 414, the controller 160 may determine whether to select another component. The controller 160 may determine whether to select another component if at least one component is left for evaluation. If at least one component is left for evaluation (‘Yes’), the controller 160 may determine to select another component. If it is determined to select another component, the method 400 returns to operation 404. Otherwise (‘No’), the method 400 ends.

While several embodiments have been provided in the present disclosure, it should be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated with another system or certain features may be omitted, or not implemented.

In addition, techniques, systems, subsystems, and methods described and illustrated in the various embodiments as discrete or separate may be combined or integrated with other systems, modules, techniques, or methods without departing from the scope of the present disclosure. Other items shown or discussed as coupled or directly coupled or communicating with each other may be indirectly coupled or communicating through some interface, device, or intermediate component whether electrically, mechanically, or otherwise. Other examples of changes, substitutions, and alterations are ascertainable by one skilled in the art and could be made without departing from the spirit and scope disclosed herein.

To aid the Patent Office, and any readers of any patent issued on this application in interpreting the claims appended hereto, applicants note that they do not intend any of the appended claims to invoke 35 U.S.C. § 112(f) as it exists on the date of filing hereof unless the words “means for” or “step for” are explicitly used in the particular claim.

What is claimed is:

1. A cooling system comprising:
a cooling architecture comprising a plurality of components, the plurality of components comprising:
at least one outdoor heat exchanger;
at least one evaporator;
at least one pump;
a plurality of racks, wherein each rack is configured to house at least one of a compressor, a flash tank, an accumulator, or an oil separator; or
a plurality of multi-valve manifolds, wherein each multi-valve manifold is configured to allow a flow of refrigerant from one component to another component of said plurality of components;
a temperature sensor circuit, positioned adjacent to a refrigerant conduit subsystem connected to a data center, and configured to capture a temperature of a coolant flowing through the refrigerant conduit subsystem; and
a controller, coupled to the cooling architecture and the temperature sensor circuit, and comprising a processor configured to:
receive the temperature of the coolant from the temperature sensor circuit;
determine whether the received temperature is more than a threshold temperature, wherein the threshold temperature is associated with a cooling demand of the data center; and
in response to determining that the received temperature is more than the threshold temperature:
determine one or more racks that meet a cooling capacity associated with the cooling demand of the data center;
determine one or more pumps of the at least one pump that meet a required flow of the refrigerant, according to the cooling demand of the data center;
communicate a first electronic signal to each of the one or more racks, wherein the first electronic signal activates a receiving rack; and
communicate a second electronic signal to each of the one or more pumps, wherein the second electronic signal activates a receiving pump.

2. The cooling system of claim 1, wherein the processor is further configured to communicate a third electronic signal to a first multi-valve manifold that is connected to the determined one or more racks to open one or more valves that allow the refrigerant to flow into the determined one or more racks, respectively.

3. The cooling system of claim 1, wherein the processor is further configured to communicate a fourth electronic signal to a second multi-valve manifold that is connected to the determined one or more pumps to open one or more valves that allow the refrigerant to flow into the determined one or more pumps, respectively.

4. The cooling system of claim 1, wherein, in response to determining that the received temperature is less than the threshold temperature, the processor is further configured to:
deactivate one or more of currently active racks from among the one or more racks; or
reduce a load of one or more of the currently active racks from among the one or more racks.

5. The cooling system of claim 1, wherein, in response to determining that the received temperature is less than the threshold temperature, the processor is further configured to:
deactivate one or more of currently active pumps from among the one or more pumps; or
reduce a flow rate of one or more of the currently active pumps from among the one or more pumps.

6. The cooling system of claim 1, wherein the processor is further configured to:
receive operational status data from each component from among the plurality of components, wherein the operational status data indicates a load carried by a respective component; and
determine a scheduling protocol for activation and deactivation of a runtime of each component based at least in part upon the received operational status data, such that an overall load is distributed substantially evenly across the plurality of components, wherein the overall load is associated with the cooling demand of the data center.

7. The cooling system of claim 1, wherein the processor is further configured to:
obtain an available power level associated with the data center;
determine that the obtained available power level has depleted more than a threshold level; and
in response to determining that the obtained available power level has depleted more than the threshold level, communicate a sixth electronic signal to one or more components of the plurality of components, wherein the sixth electronic signal causes a runtime of each of the one or more components is adjusted to maintain the cooling capacity associated with the cooling demand of the data center.

8. A method of operating a cooling system comprising:
receiving temperature of a coolant from a temperature sensor circuit, wherein the temperature sensor circuit is positioned adjacent to a refrigerant conduit subsystem connected to a data center, and configured to capture the temperature of a coolant flowing through the refrigerant conduit subsystem;
determining whether the received temperature is more than a threshold temperature, wherein the threshold temperature is associated with a cooling demand of the data center; and
in response to determining that the received temperature is more than the threshold temperature:
determining one or more racks that meet a cooling capacity associated with the cooling demand of the data center, wherein each rack is configured to house at least one of a compressor, a flash tank, an accumulator, or an oil separator;
determining one or more pumps that meet a required flow of a refrigerant, according to the cooling demand of the data center;
communicating a first electronic signal to each of the one or more racks, wherein the first electronic signal activates a receiving rack; and
communicating a second electronic signal to each of the one or more pumps, wherein the second electronic signal activates a receiving pump.

9. The method of claim 8, further comprising communicating a third electronic signal to a first multi-valve manifold that is connected to the determined one or more racks to open one or more valves that allow the refrigerant to flow into the determined one or more racks, respectively.

10. The method of claim 8, further comprising communicating a fourth electronic signal to a second multi-valve manifold that is connected to the determined one or more pumps to open one or more valves that allow the refrigerant to flow into the determined one or more pumps, respectively.

11. The method of claim 8, wherein, in response to determining that the received temperature is less than the threshold temperature, to the method further comprises:
deactivating one or more of currently active racks from among the one or more racks; or
reducing a load of one or more of the currently active racks from among the one or more racks.

12. The method of claim 8, wherein, in response to determining that the received temperature is less than the threshold temperature, the method further comprises:
deactivating one or more of currently active pumps from among the one or more pumps; or
reducing a flow rate of one or more of the currently active pumps from among the one or more pumps.

13. The method of claim 8, further comprising:
receiving operational status data from each component from among plurality of components associated with the cooling system, wherein the operational status data indicates a load carried by a respective component; and
determining a scheduling protocol for activation and deactivation of a runtime of each component based at least in part upon the received operational status data, such that an overall load is distributed substantially evenly across the plurality of components, wherein the overall load is associated with the cooling demand of the data center.

14. The method of claim 8, further comprising:
obtaining an available power level associated with the data center;
determining that the obtained available power level has depleted more than a threshold level; and
in response to determining that the obtained available power level has depleted more than the threshold level, communicating a sixth electronic signal to one or more components of the cooling system, wherein the sixth electronic signal causes a runtime of each of the one or more components is adjusted to maintain the cooling capacity associated with the cooling demand of the data center.

15. A controller of a cooling system comprising:
a processor, coupled with a temperature sensor circuit, and configured to:
receive temperature of a coolant from the temperature sensor circuit, wherein the temperature sensor circuit is positioned adjacent to a refrigerant conduit subsystem connected to a data center, and configured to capture the temperature of a coolant flowing through the refrigerant conduit subsystem;
determine whether the received temperature is more than a threshold temperature, wherein the threshold temperature is associated with a cooling demand of the data center; and
in response to determining that the received temperature is more than the threshold temperature:
determine one or more racks that meet a cooling capacity associated with the cooling demand of the data center, wherein each rack is configured to house at least one of a compressor, a flash tank, an accumulator, or an oil separator;
determine one or more pumps that meet a required flow of the refrigerant, according to the cooling demand of the data center;
communicate a first electronic signal to each of the one or more racks, wherein the first electronic signal activates a receiving rack; and
communicate a second electronic signal to each of the one or more pumps, wherein the second electronic signal activates a receiving pump.

16. The controller of claim 15, wherein the processor is further configured to communicate a third electronic signal to a first multi-valve manifold that is connected to the determined one or more racks to open one or more valves that allow the refrigerant to flow into the determined one or more racks, respectively.

17. The controller of claim 15, wherein the processor is further configured to communicate a fourth electronic signal to a second multi-valve manifold that is connected to the determined one or more pumps to open one or more valves that allow the refrigerant to flow into the determined one or more pumps, respectively.

18. The controller of claim 15, wherein, in response to determining that the received temperature is less than the threshold temperature, the processor is further configured to:
deactivate one or more of currently active racks from among the one or more racks; or
reduce a load of one or more of the currently active racks from among the one or more racks.

19. The controller of claim 15, wherein, in response to determining that the received temperature is less than the threshold temperature, the processor is further configured to:
deactivate one or more of currently active pumps from among the one or more pumps; or
reduce a flow rate of one or more of the currently active pumps from among the one or more pumps.

20. The controller of claim 15, wherein the processor is further configured to:
receive operational status data from each component from among a plurality of components associated with the cooling system, wherein the operational status data indicates a load carried by a respective component; and
determine a scheduling protocol for activation and deactivation of a runtime of each component based at least in part upon the received operational status data, such that an overall load is distributed substantially evenly across the plurality of components, wherein the overall load is associated with the cooling demand of the data center.
